(19) United States
(12) Patent Application Publication
(10) Pub. No.: US 2012/0001177 A1
(43) Pub. Date: Jan. 5, 2012

(54) SEMICONDUCTOR DEVICE

(75) Inventors: Asako Miyoshi, Kyoto (JP); Shigeo Chaya, Shiga (JP)

(73) Assignee: Panasonic Corporation, Osaka (JP)

(21) Appl. No.: 13/232,516

(22) Filed: Sep. 14, 2011

Related U.S. Application Data
(63) Continuation of application No. PCT/JP2010/001009, filed on Feb. 17, 2009.

(30) Foreign Application Priority Data
Mar. 17, 2009 (JP) 2009-064379

(51) Int. Cl. H01L 23/538; H01L 23/535

(52) U.S. Cl. 257/48; 257/777; 257/E23.169; 257/E23.168

(57) ABSTRACT

In a multi-chip semiconductor device, a second semiconductor chip is stacked on a first semiconductor chip with an adhesive layer being interposed therebetween, and the first and second semiconductor chips are sealed by resin containing a mixture of, e.g., a filler. The first semiconductor chip includes a first region on a surface of which the second semiconductor chip is stacked, and a second region on a surface of which the second semiconductor chip does not stacked. In one of interconnect layers including an uppermost layer, a wiring pattern is not provided, which extends across a border between the first and second regions.

### CROSS-REFERENCE TO RELATED APPLICATION

This is a continuation of PCT International Application PCT/JP2010/001009 filed on Feb. 17, 2010, which claims priority to Japanese Patent Application No. 2009-064379 filed on Mar. 17, 2009. The disclosures of these applications including the specifications, the drawings, and the claims are hereby incorporated by reference in their entirety.

### BACKGROUND

The present disclosure relates to a multilayer semiconductor device in which a plurality of semiconductor chips are stacked.

In recent years, a configuration in which a plurality of semiconductor chips are stacked to form a single semiconductor device has been employed in order to reduce a mounting area. In the multilayer semiconductor device of this type, the semiconductor chips are stacked with an adhesive layer being interposed therebetween, and are sealed by, e.g., molding resin. Recently, even a semiconductor device in which three or more semiconductor chips are stacked and are sealed by molding resin has been developed.

FIG. 39 illustrates an example of a configuration of a conventional multi-chip semiconductor device. A second semiconductor chip 2 is stacked on a first semiconductor chip 1 with an adhesive layer 3 being interposed therebetween, and the stacked semiconductor chips 1, 2 are sealed by molding resin 5 containing a mixture. The molding resin 5 is made of a mixture of various materials, and a filler 4 has the largest volume among such materials. Since a filler has a coefficient of thermal expansion, which is close to that of silicon, the filler is added to reduce or prevent package cracks and increase resin strength after molding. When sealing the stacked first semiconductor chips 1, 2, a molding pressure may press the filler 4 contained in the molding resin 5 into end portions of the adhesive layer 3, and then the filler 4 may be sandwiched between the first and second semiconductor chips 1, 2. This causes damage in a surface region of the first semiconductor chip 1, on which the second semiconductor chip 2 is stacked, resulting in improper assembly.

For the foregoing problem, techniques of making a particle size of the filler 4 larger than a thickness of the adhesive layer 3 as illustrated in FIG. 40, and of making an area of the adhesive layer 3 on a surface of the first semiconductor chip 1 larger than an area of the second semiconductor chip 2 as illustrated in FIG. 41 have been proposed. This reduces or prevents entering of the filler 4 between the first and second semiconductor chips 1, 2, thereby reducing the improper assembly caused due to the chip damage (see Japanese Patent Publication No. 2006-054359).

### SUMMARY

However, if material(s) of the filler is/are changed in order to increase the particle size of the filler, warpage of a package and voids are caused, and therefore there is a possibility that specifications required for a semiconductor package cannot be met. In a configuration in which an area of the adhesive layer is different from that of the second semiconductor chip, the adhesive layer and the second semiconductor chip cannot be simultaneously cut. As a result, the number of assembly steps are increased, thereby increasing a cost.

In view of the foregoing problem, it is an objective of the present disclosure to, in a multi-chip semiconductor device, reduce improper assembly due to chip damage caused by a filler contained in sealing resin without causing a cost increase.

The present disclosure is intended for a semiconductor device including a first semiconductor chip; a second semiconductor chip stacked on the first semiconductor chip with an adhesive layer being interposed therebetween; and resin for sealing the first and second semiconductor chips.

In a first aspect of the present disclosure, the first semiconductor chip includes a first region on a surface of which the second semiconductor chip is stacked, and a second region on a surface of which the second semiconductor chip is not stacked. In at least one of interconnect layers including an uppermost layer of the first semiconductor chip, a wiring pattern for an interconnect to be used for an operation of the first semiconductor chip is provided so as not to extend across a border between the first and second regions.

According to the first aspect of the present disclosure, even if a mixture contained in the resin enters end portions of the adhesive layer by a sealing pressure of the resin, and a surface of the first semiconductor chip is damaged, the damage provides an impact only on the first region on the surface of which the second semiconductor chip is stacked. As in the foregoing, a predetermined condition for arranging the interconnect in the first region is provided, and therefore the semiconductor device can be normally operated even if the damage of the surface of the first semiconductor chip is caused due to the mixture. Thus, improper assembly can be reduced, thereby realizing a cost reduction.

In a second aspect of the present disclosure, the first semiconductor chip includes a third region which is a circular or rectangular region on a surface of which a circumferential end portion of the second semiconductor chip is positioned, a fourth region which is a region inside the third region, and a fifth region which is a region outside the third region. In at least one of interconnect layers including an uppermost layer of the first semiconductor chip, a wiring pattern for an interconnect to be used for an operation of the first semiconductor chip is provided so as not to extend across a border between the third and fourth regions and a border between the third and fifth regions.

According to the second aspect of the present disclosure, even if the mixture contained in the resin enters the end portions of the adhesive layer by the sealing pressure of the resin, and the surface of the first semiconductor chip is damaged, the damage provides an impact only on the third region which is the circular or rectangular region on the surface of which the circumferential end portion of the second semiconductor chip is positioned. As in the foregoing, a predetermined condition for arranging the interconnect in the third region is provided, and therefore the semiconductor device can be normally operated even if the damage of the surface of the first semiconductor chip is caused due to the mixture. Thus, the improper assembly can be reduced, thereby realizing the cost reduction.

In a third aspect of the present disclosure, the first semiconductor chip includes a first region on a surface of which the second semiconductor chip is stacked, and a second region on a surface of which the second semiconductor chip is not stacked. In at least one of interconnect layers including an uppermost layer of the first semiconductor chip, a plurality of wiring patterns which are at the same potential are arranged so as to extend across a border between the first and second regions.

According to the third aspect of the invention, even if the mixture contained in the resin enters the end portions of the adhesive layer by the sealing pressure of the resin, and the surface of the first semiconductor chip is damaged, it is less likely to damage all of the plurality of the wiring patterns. As in the foregoing, a predetermined condition for arranging the interconnect in the first region is provided, and therefore the semiconductor device can be normally operated even if the damage of the surface of the first semiconductor chip is caused due to the mixture. Thus, the improper assembly can be reduced, thereby realizing the cost reduction.

In a fourth aspect of the present disclosure, the first semiconductor chip includes a third region which is a circular or rectangular region on a surface of which a circumferential end portion of the second semiconductor chip is positioned, a fourth region which is a region inside the third region, and a fifth region which is a region outside the third region. In at least one of interconnect layers including an uppermost layer of the first semiconductor chip, a plurality of wiring patterns which are at the same potential are arranged so as to extend across a border between the third and fourth regions.

In a fifth aspect of the present disclosure, the first semiconductor chip includes a third region which is a circular or rectangular region on a surface of which a circumferential end portion of the second semiconductor chip is positioned, a fourth region which is a region inside the third region, and a fifth region which is a region outside the third region. In at least one of interconnect layers including an uppermost layer of the first semiconductor chip, a plurality of wiring patterns which are at the same potential are arranged so as to extend across a border between the third and fifth regions.

According to the fourth and fifth aspects of the present disclosure, even if the mixture contained in the resin enters the end portions of the adhesive layer by the sealing pressure of the resin, and the surface of the first semiconductor chip is damaged, it is less likely to damage all of the plurality of the wiring patterns. As in the foregoing, a predetermined condition for arranging the interconnect in the third region is provided, and therefore the semiconductor device can be normally operated even if the damage of the surface of the first semiconductor chip is caused due to the mixture. Thus, the improper assembly can be reduced, thereby realizing the cost reduction.

In a sixth aspect of the present disclosure, the first semiconductor chip includes a memory cell array, and the memory cell array is arranged in an area including a region of the first semiconductor chip, on a surface of which the second semiconductor chip is stacked.

According to the sixth aspect of the present disclosure, even if the mixture contained in the resin enters the end portions of the adhesive layer by the sealing pressure of the resin, and the surface of the first semiconductor chip is damaged, the damage provides an impact only on the memory cell array arranged in the region of the first semiconductor chip, on the surface of which the second semiconductor chip is stacked. As in the foregoing, even if the damage of the surface of the first semiconductor chip is caused due to the mixture, the semiconductor device can be normally operated by, e.g., setting an access to a damaged memory cell in an inhibited state or redundantly replacing a damaged memory cell. Thus, the improper assembly can be reduced, thereby realizing the cost reduction.

According to the present disclosure, the impact of the chip damage caused due to the mixture contained in the resin is provided only on the first region on the surface of which the second semiconductor chip is stacked, the third region which is the circular or rectangular region on the surface of which the circumferential end portion of the second semiconductor chip is positioned, or the memory cell array arranged in the region of the first semiconductor chip, on the surface of which the second semiconductor chip is stacked. Thus, even if the chip damage is caused, the semiconductor device can be normally operated, thereby reducing the improper assembly.

### BRIEF DESCRIPTION OF THE DRAWINGS

FIG. 1 is a cross-sectional view illustrating a configuration of a semiconductor device of a first embodiment.

FIG. 2 is a plan view illustrating the configuration of the semiconductor device of the first embodiment.

FIG. 3 is a plan view illustrating a state of an interconnect layer of a first semiconductor chip in the semiconductor device of the first embodiment.

FIG. 4 is a plan view illustrating the state of the interconnect layer of the first semiconductor chip in the semiconductor device of the first embodiment.

FIG. 5 is a plan view illustrating another state of the interconnect layer of the first semiconductor chip in the semiconductor device of the first embodiment.

FIG. 6 is a plan view illustrating still another state of the interconnect layer of the first semiconductor chip in the semiconductor device of the first embodiment.

FIG. 7 is a plan view illustrating still another state of the interconnect layer of the first semiconductor chip in the semiconductor device of the first embodiment.

FIG. 8 is a plan view illustrating still another state of the interconnect layer of the first semiconductor chip in the semiconductor device of the first embodiment.

FIG. 9 is a plan view illustrating still another state of the interconnect layer of the first semiconductor chip in the semiconductor device of the first embodiment.

FIG. 10 is a cross-sectional view illustrating a configuration of a semiconductor device of a second embodiment.

FIG. 11 is a plan view illustrating the configuration of the semiconductor device of the second embodiment.

FIG. 12 is a plan view illustrating another configuration of the semiconductor device of the second embodiment.

FIG. 13 is a plan view illustrating a state of an interconnect layer of a first semiconductor chip in the semiconductor device of the second embodiment.

FIG. 14 is a plan view illustrating another state of the interconnect layer of the first semiconductor chip in the semiconductor device of the second embodiment.

FIG. 15 is a plan view illustrating still another state of the interconnect layer of the first semiconductor chip in the semiconductor device of the second embodiment.

FIG. 16 is a plan view illustrating still another state of the interconnect layer of the first semiconductor chip in the semiconductor device of the second embodiment.

FIG. 17 is a plan view illustrating still another state of the interconnect layer of the first semiconductor chip in the semiconductor device of the second embodiment.

FIG. 18 is a plan view illustrating still another state of the interconnect layer of the first semiconductor chip in the semiconductor device of the second embodiment.

FIG. 19 is a plan view illustrating still another state of the interconnect layer of the first semiconductor chip in the semiconductor device of the second embodiment.

FIG. 20 is a plan view illustrating still another state of the interconnect layer of the first semiconductor chip in the semiconductor device of the second embodiment.

FIG. 21 is a plan view illustrating still another state of the interconnect layer of the first semiconductor chip in the semiconductor device of the second embodiment.

FIG. 22 is a plan view illustrating still another state of the interconnect layer of the first semiconductor chip in the semiconductor device of the second embodiment.

FIG. 23 is a plan view illustrating still another state of the interconnect layer of the first semiconductor chip in the semiconductor device of the second embodiment.

FIG. 24 is a plan view illustrating still another state of the interconnect layer of the first semiconductor chip in the semiconductor device of the second embodiment.

FIG. 25 is a plan view illustrating still another state of the interconnect layer of the first semiconductor chip in the semiconductor device of the second embodiment.

FIG. 26 is a cross-sectional view illustrating a configuration of a semiconductor device of a third embodiment.

FIG. 27 is a plan view illustrating a state of an interconnect layer of a first semiconductor chip in the semiconductor device of the third embodiment.

FIG. 28 is a cross-sectional view illustrating another configuration of the semiconductor device of the third embodiment.

FIG. 29 is a cross-sectional view illustrating still another configuration of the semiconductor device of the third embodiment.

FIG. 30 is a cross-sectional view illustrating a configuration of a semiconductor device of a fourth embodiment.

FIG. 31 is a plan view illustrating a state of an interconnect layer of a first semiconductor chip in the semiconductor device of the fourth embodiment.

FIG. 32 is a plan view illustrating another state of the interconnect layer of the first semiconductor chip in the semiconductor device of the fourth embodiment.

FIG. 33 is a cross-sectional view illustrating another configuration of the semiconductor device of the fourth embodiment.

FIG. 34 is a cross-sectional view illustrating still another configuration of the semiconductor device of the fourth embodiment.

FIG. 35 is a cross-sectional view illustrating still another configuration of the semiconductor device of the fourth embodiment.

FIG. 36 is a cross-sectional view illustrating still another configuration of the semiconductor device of the fourth embodiment.

FIG. 37 is a cross-sectional view illustrating a configuration of a semiconductor device of a fifth embodiment.

FIG. 38 is a cross-sectional view illustrating another configuration of the semiconductor device of the fifth embodiment.

FIG. 39 is a cross-sectional view illustrating a conventional example.

FIG. 40 is a cross-sectional view illustrating another conventional example.

FIG. 41 is a cross-sectional view illustrating still another conventional example.

### DETAILED DESCRIPTION

Embodiments of the present disclosure will be described below with reference to the drawings.

### First Embodiment

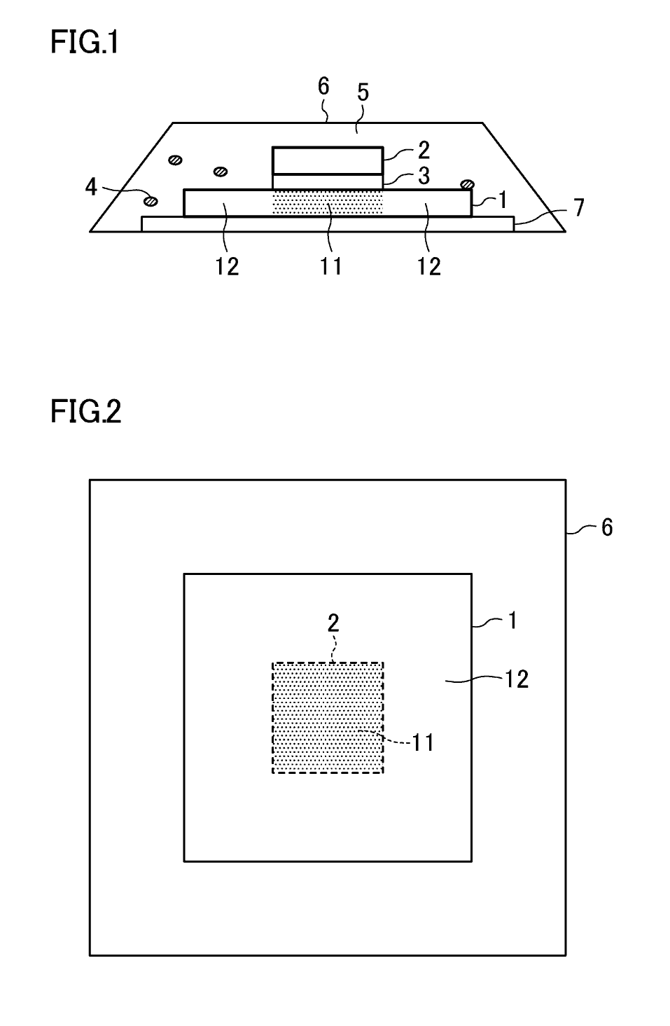

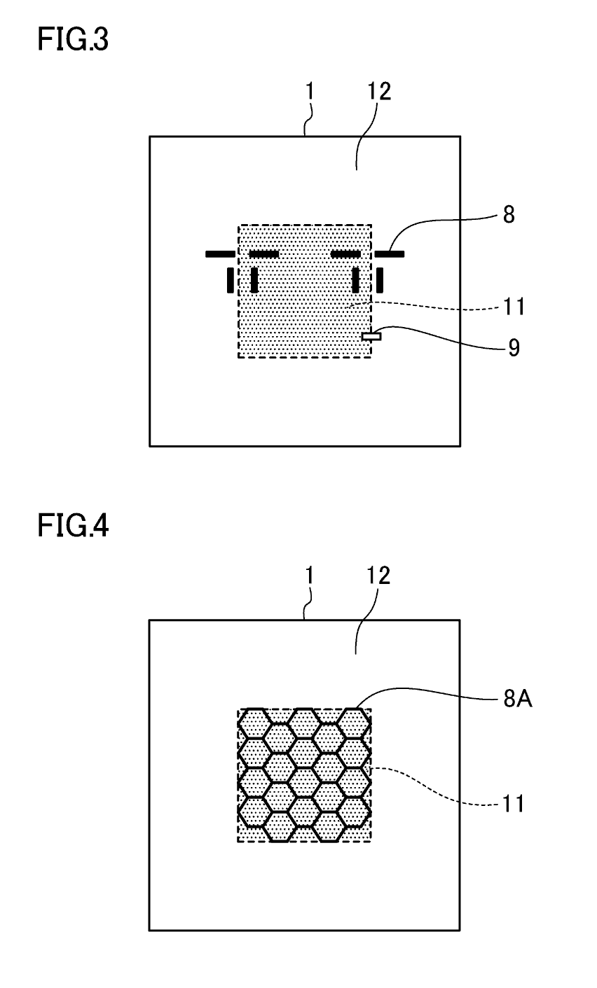

FIGS. 1 and 2 are a cross-sectional view and a plan view illustrating a configuration of a multi-chip semiconductor device of a first embodiment, and FIGS. 3-9 are plan views illustrating states of an interconnect layer of a first semiconductor chip 1 of the present embodiment.

In FIGS. 1 and 2, a semiconductor device 6 includes the first semiconductor chip 1 fixed to a die pad 7, a second semiconductor chip 2 stacked on the first semiconductor chip 1 with an adhesive layer 3 being interposed therebetween, and molding resin 5 provided as an example of resin for sealing the first and second semiconductor chips 1, 2. The second semiconductor chip 2 is fixed onto the first semiconductor chip 1 by the adhesive layer 3. The molding resin 5 is, e.g., epoxy resin, and contains a mixture having a filler 4 as a main component.

The first semiconductor chip 1 is divided into a first region 11 on a surface of which the second semiconductor chip 2 is stacked, and a second region 12 on a surface of which the second semiconductor chip 2 is not stacked. In the present embodiment, as illustrated in FIG. 3, a wiring pattern in which an interconnect extends across a border between the first and second regions 11, 12 is not provided in at least one of interconnect layers including an uppermost layer. That is, a wiring pattern 8 for an interconnect to be used for an operation of the first semiconductor chip 1 is provided so as not to extend across the border between the first and second regions 11, 12. Note that a dummy pattern 9 extending across the border between the first and second regions 11, 12 may be provided.

According to such a configuration, even if the filler 4 contained in the molding resin 5 enters end portions of the adhesive layer 3 by a sealing pressure of the molding resin 5, and a surface of the first semiconductor chip 1 is damaged, the damage provides an impact only on the first region 11. As in the foregoing, a predetermined condition for arranging the interconnects in the first region 11 is provided, and therefore the semiconductor device 6 can be normally operated even if the damage of the surface of the first semiconductor chip 1 is caused due to the filler 4. Thus, improper assembly can be reduced, thereby realizing a cost reduction.

For example, it is preferred that the interconnects to be used for the operation of the first semiconductor chip 1 are not arranged in the first region 11 in the at least one of interconnect layers including the uppermost layer. In such a case, since there are no interconnects to be used for the operation of the first semiconductor chip 1 in the first region 11, the first semiconductor chip 1 and the semiconductor device 6 can be normally operated even if the surface of the first semiconductor chip 1 is damaged due to the filler 4.

Alternatively, in the at least one of interconnect layers including the uppermost layer, only any one of a disused interconnect, a disused element, and a dummy pattern which are not to be used for the operation of the first semiconductor chip 1 may be arranged in the first region 11. In such a case, even if the surface of the first semiconductor chip 1 is damaged due to the filler 4, the damage provides an impact only on the disused interconnect, the disused element, or the dummy pattern arranged in the first region 11. In addition, the disused interconnect, the disused element, or the dummy pattern functions to absorb mechanical or electrical damage when the surface of the first semiconductor chip 1 is damaged. Thus, the first semiconductor chip 1 and the semiconductor device 6 can be normally operated.

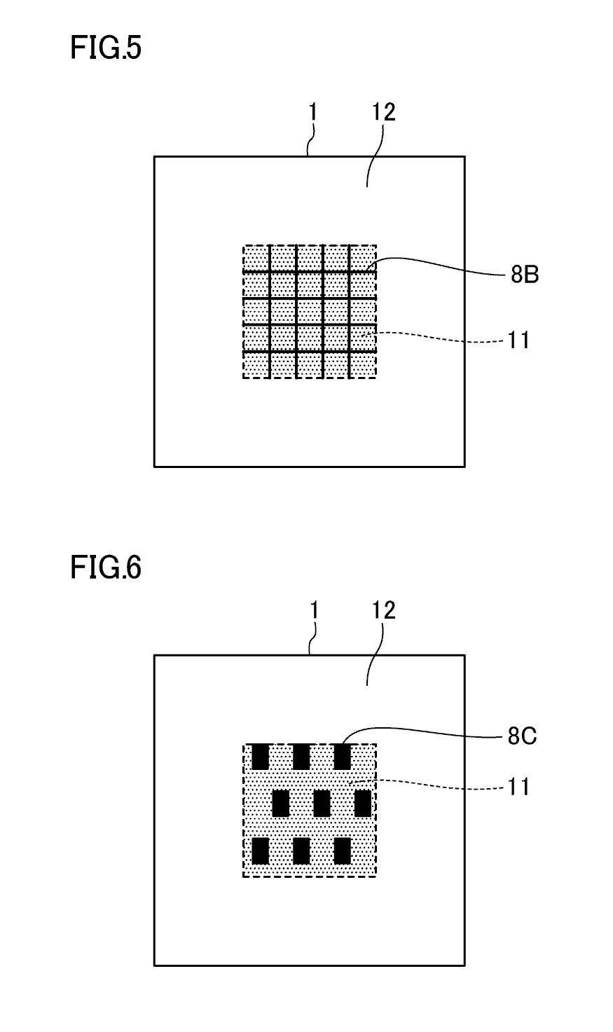

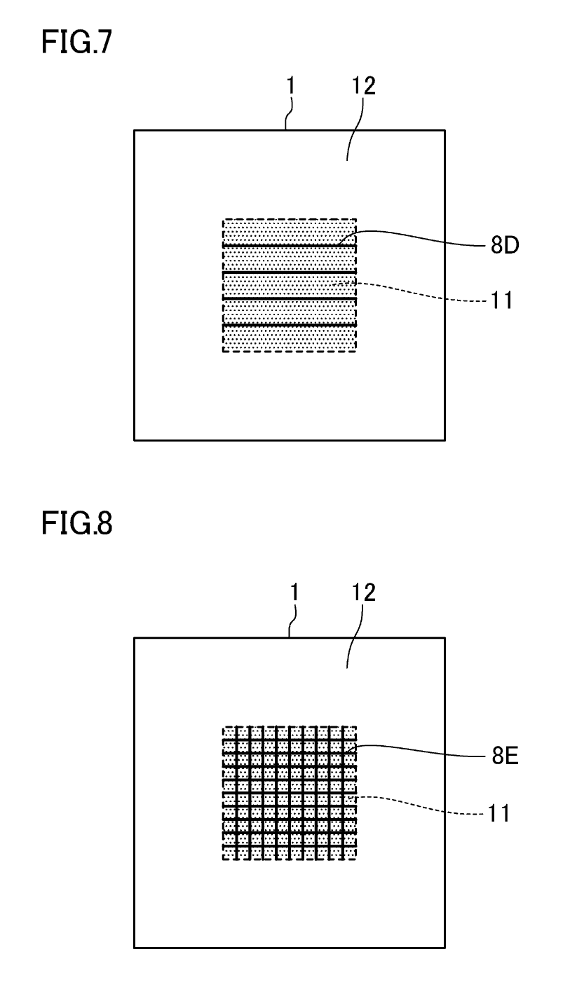

Note that, e.g., an element for evaluating transistor characteristics may be used as the disused element. In such a case, after the second semiconductor chip 2 is stacked on the first semiconductor chip 1, the transistor characteristics are evaluated by the disused element, thereby measuring the degree of the sealing pressure of the molding resin 5. In addition, e.g., a honeycomb-shaped wiring pattern 8A as illustrated in FIG. 4 may be used as the disused interconnect. Alternatively, the following wiring patterns may be used: a wiring pattern 8B which is a grid pattern as illustrated in FIG. 5; a rectangular wiring pattern 8C as illustrated in FIG. 6; and a wiring pattern 8D which is a striped pattern as illustrated in FIG. 7.

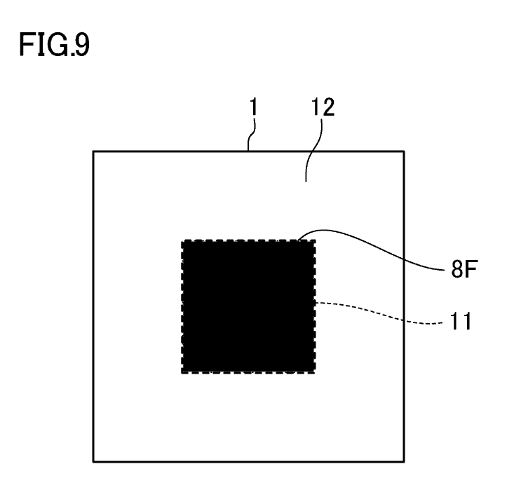

Further, wiring patterns 8E, 8F may be provided so as to cover an entire surface of the first region 11 as illustrated in FIGS. 8 and 9. In such a case, even if the surface of the first semiconductor chip 1 is damaged due to the filler 4, the damage provides an impact only on the wiring pattern 8E, 8F in which the interconnects are formed so as to cover the entire surface of the first region 11. In addition, the wiring pattern 8E, 8F functions to absorb the mechanical or electrical damage when the surface of the first semiconductor chip 1 is damaged. Thus, the first semiconductor chip 1 and the semiconductor device 6 can be normally operated.

Note that the condition for arranging the interconnects in the first region 11 may be provided only to the uppermost layer of a plurality of interconnect layers of the first semiconductor chip 1. Alternatively, a signal line and a power source line extending across the border between the first and second regions 11, 12 may be arranged in the interconnect layer other than the uppermost layer.

Note that the adhesive layer 3 may be in any forms, i.e., may be a substrate such as an interposer, a sheet, a liquid, etc.

### Second Embodiment

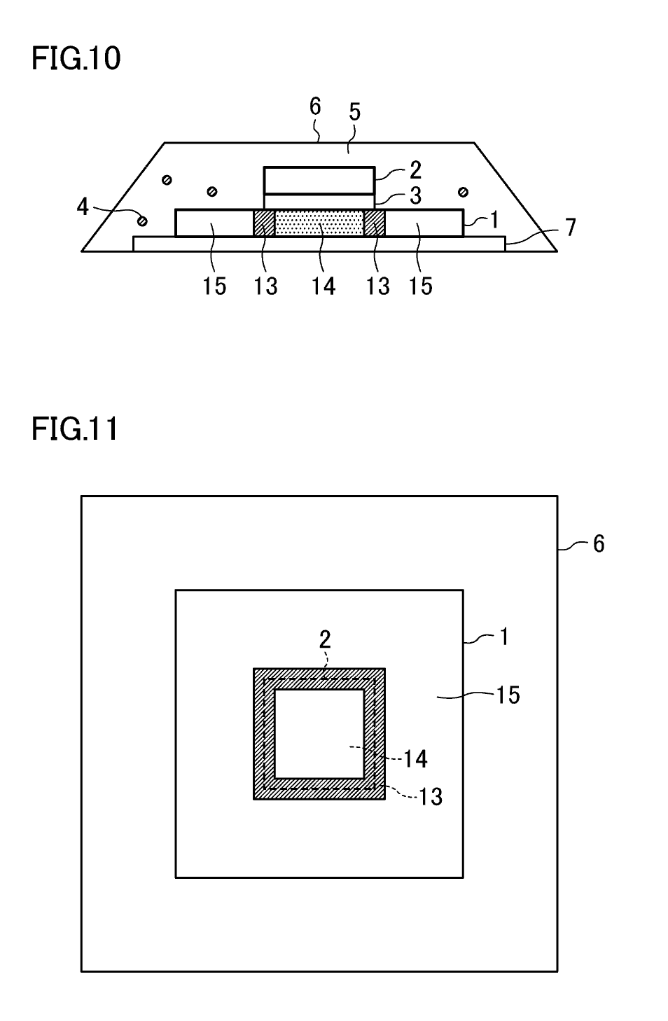

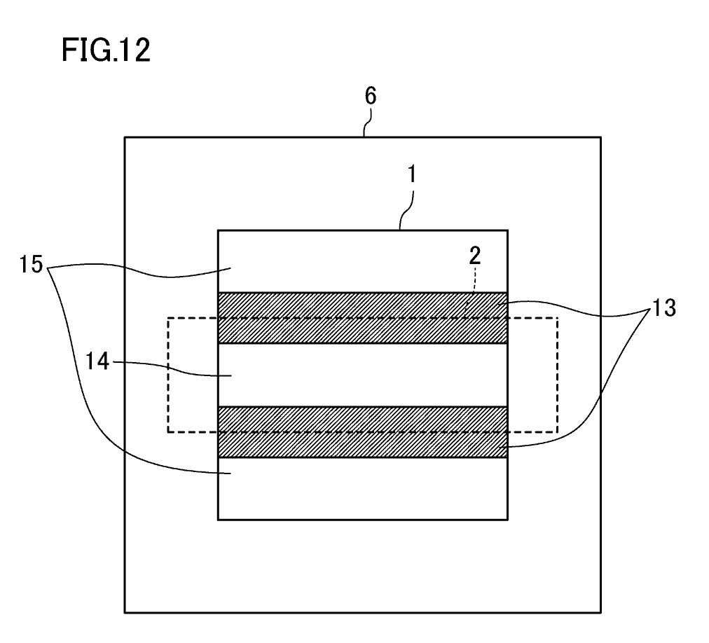

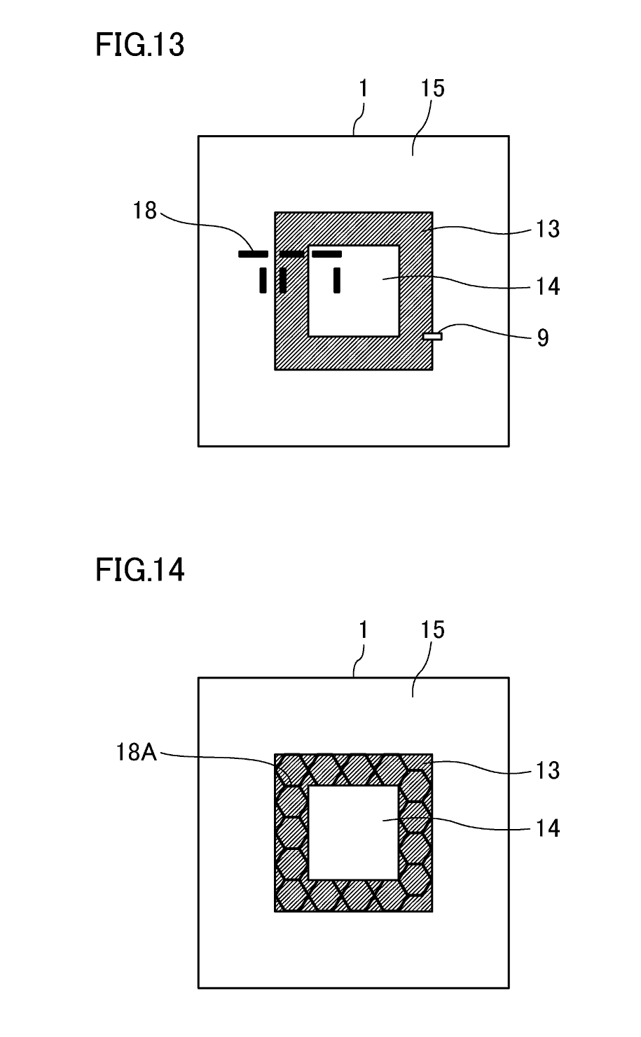

FIG. 10 is a cross-sectional view illustrating a multi-chip semiconductor device of a second embodiment, and FIGS. 11 and 12 are plan views thereof. FIGS. 13-25 are plan views of an interconnect layer of a first semiconductor chip 1 of the present embodiment.

In FIGS. 10-12, a semiconductor device 6 includes the first semiconductor chip 1 fixed to a die pad 7, a second semiconductor chip 2 stacked on the first semiconductor chip 1 with an adhesive layer 3 being interposed therebetween, and molding resin 5 provided as an example of resin for sealing the first and second semiconductor chips 1, 2. The molding resin 5 is, e.g., epoxy resin, and contains a mixture having a filler 4 as a main component.

The first semiconductor chip 1 is divided into a third region 13 which is a circular or rectangular region on a surface of which a circumferential end portion of the second semiconductor chip 2 is positioned, a fourth region 14 which is a region inside the third region 13, and a fifth region 15 which is a region outside the third region 13. The third region 13 includes an outer circumferential portion of the first region 11 described in the first embodiment, and extends over the second region 12. The fourth region 14 and the fifth region 15 correspond part of the first region 11 other than the third region 13 and part of the second region 12 other than the third region 13, respectively. Note that the third region 13 is a circular region in FIG. 11, and is a rectangular region in FIG. 12.

In the present embodiment, as illustrated in FIG. 13, a wiring pattern in which an interconnect extends across a border between the third region 13 and the fourth region 14 and a wiring pattern in which an interconnect extends across a border between the third region 13 and the fifth region 15 are not provided in at least one of interconnect layers including an uppermost layer. That is, a wiring pattern 18 for an interconnect to be used for an operation of the first semiconductor chip 1 is provided so as not to extend across the borders between the third and fourth regions 13, 14 and the third and fifth regions 13, 15. Note that a dummy pattern extending across the border between the third and fourth regions 13, 14 or a dummy pattern extending across the border between the third and fifth regions 13, 15 may be provided.

According to such a configuration, even if the filler 4 contained in the molding resin 5 enters end portions of the adhesive layer 3 by a sealing pressure of the molding resin 5, and a surface of the first semiconductor chip 1 is damaged, the damage provides an impact only on the third region 13. As in the foregoing, a predetermined condition for arranging the interconnects in the third region 13 is provided, and therefore the semiconductor device 6 can be normally operated even if the damage of the surface of the first semiconductor chip 1 is caused due to the filler 4. Thus, improper assembly can be reduced, thereby realizing a cost reduction. According to the present embodiment, since the interconnects are formed across the circular or rectangular region on the surface of which the circumferential end portion of the second semiconductor chip is positioned, considering the impact of the filler, the similar advantages can be realized if a position of the second semiconductor chip is displaced.

For example, it is preferred that the interconnects to be used for the operation of the first semiconductor chip 1 are not arranged in the third region 13 or the third and fourth regions 13, 14 in the at least one of interconnect layers including the uppermost layer. In such a case, since there are no interconnects to be used for the operation of the first semiconductor chip 1 in the third region 13, the first semiconductor chip 1 and the semiconductor device 6 can be normally operated even if the surface of the first semiconductor chip 1 is damaged due to the filler 4.

Alternatively, in the at least one of interconnect layers including the uppermost layer, only any one of a disused interconnect, a disused element, and a dummy pattern which are not to be used for the operation of the first semiconductor chip 1 may be arranged in the third region 13 or the third and fourth regions 13, 14. In such a case, even if the surface of the first semiconductor chip 1 is damaged due to the filler 4, the damage provides an impact only on the disused interconnect, the disused element, or the dummy pattern arranged in the third region 13. In addition, the disused interconnect, the disused element, or the dummy pattern functions to absorb mechanical or electrical damage when the surface of the first semiconductor chip 1 is damaged. Thus, the first semiconductor chip 1 and the semiconductor device 6 can be normally operated.

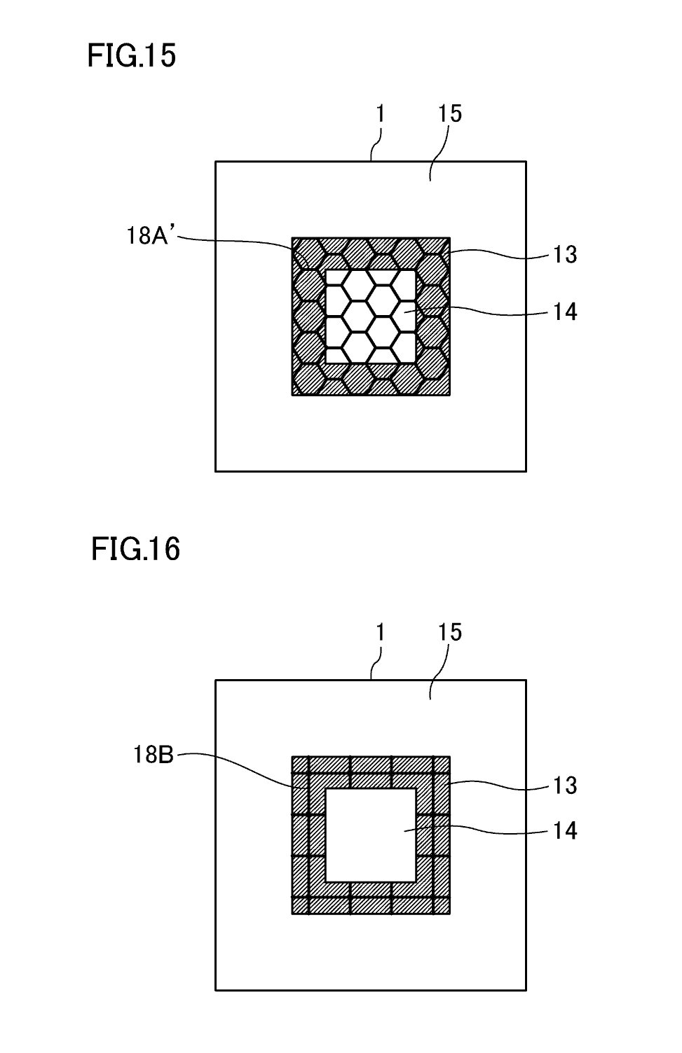

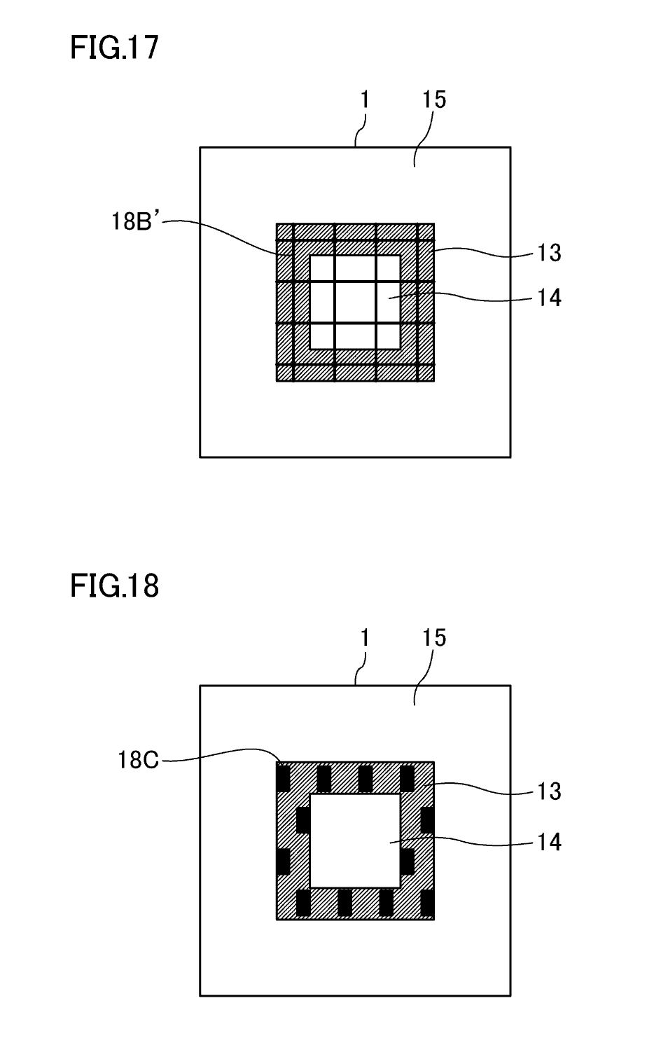

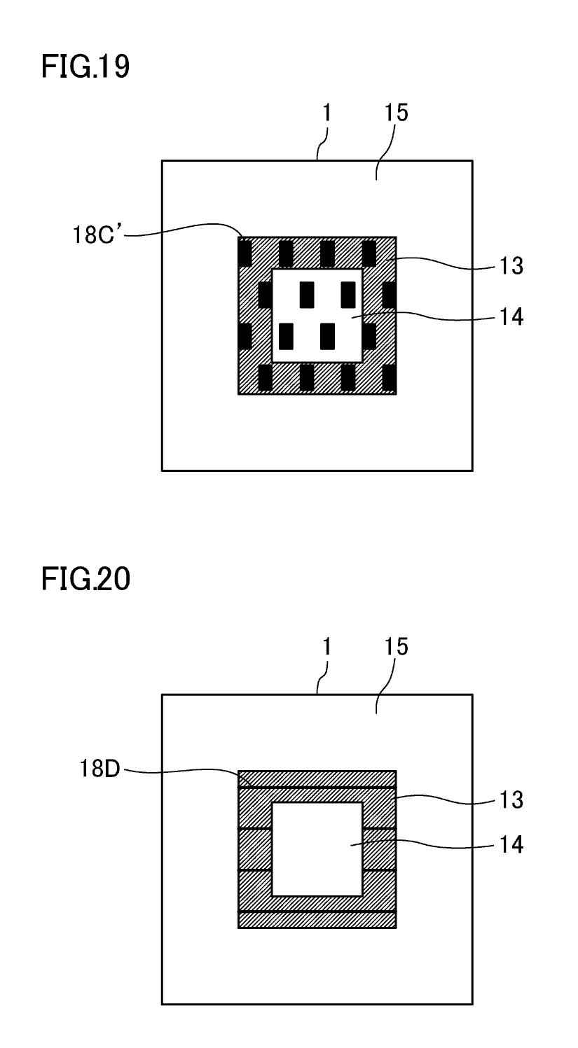

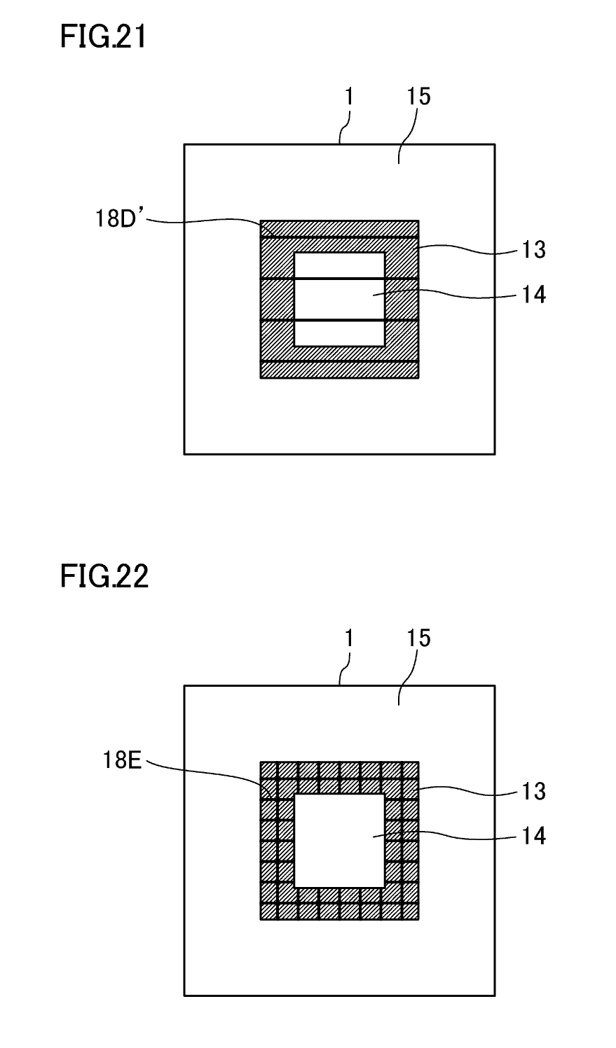

Note that, e.g., an element for evaluating transistor characteristics may be used as the disused element. In such a case, after the second semiconductor chip 2 is stacked on the first semiconductor chip 1, the transistor characteristics are evaluated by the disused element, thereby measuring the degree of the sealing pressure of the molding resin 5. In addition, e.g., a honeycomb-shaped wiring pattern 18A, 18A′ as illustrated in FIG. 14 or 15 may be used as the disused interconnect. Alternatively, the following wiring patterns may be used: a wiring pattern 18B, 18B′ which is a grid pattern as illustrated in FIG. 16 or 17; a rectangular wiring pattern 18C, 18C′ as illustrated in FIG. 18 or 19; and a wiring pattern 18D, 18D′ which is a striped pattern as illustrated in FIG. 20 or 21.

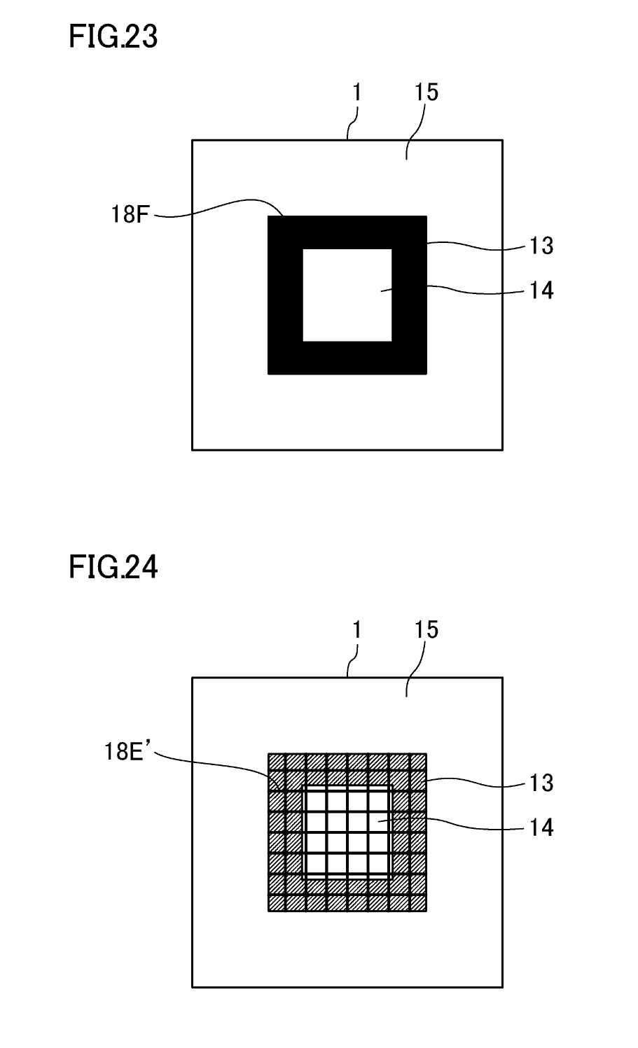

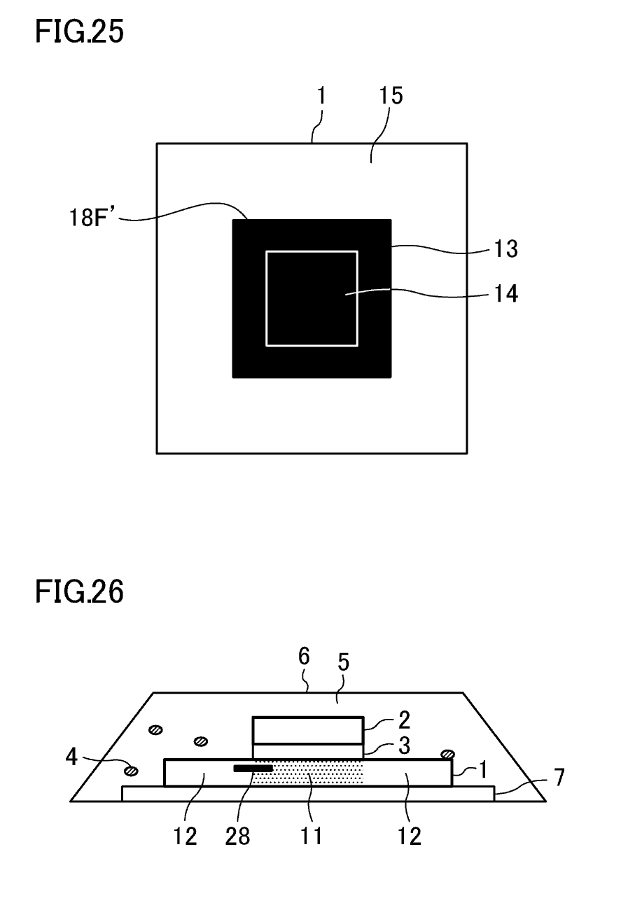

Further, wiring patterns 18E, 18F may be provided so as to cover an entire surface of the third region 13 as illustrated in FIGS. 22 and 23. Alternatively, wiring patterns 18E′, 18F′ may be provided so as to cover an entire surface of the third and fourth regions 13, 14 as illustrated in FIGS. 24 and 25. In such a case, even if the surface of the first semiconductor chip 1 is damaged due to the filler 4, the damage provides an impact only on the wiring pattern 18E, 18F, 18E′, 18F′ in which the interconnects are formed so as to cover the entire surface of the third region 13 or the third and fourth regions 13, 14. In addition, the wiring pattern 18E, 18F, 18E′, 18F′ functions to absorb the mechanical or electrical damage when the surface of the first semiconductor chip 1 is damaged. Thus, the first semiconductor chip 1 and the semiconductor device 6 can be normally operated.

Note that the condition for arranging the interconnects in the third region 13 or the third and fourth regions 13, 14 may be provided only to the uppermost layer of a plurality of interconnect layers of the first semiconductor chip 1. Alternatively, a signal line and a power source line which extend across the border between the third and fourth regions 13, 14, and a signal line and a power source line which extend across the border between the third and fifth regions 13, 15 may be arranged in the interconnect layer other than the uppermost layer.

Note that it is preferred that a width of the third region 13 is larger than a particle size of the filler 4. This ensures that, even if the first semiconductor chip 1 is damaged, the damage is provided only on the third region 13. Thus, the first semiconductor chip 1 and the semiconductor device 6 can be normally operated.

Note that the adhesive layer 3 may be in any forms, i.e., may be a substrate such as an interposer, a sheet, a liquid, etc.

### Third Embodiment

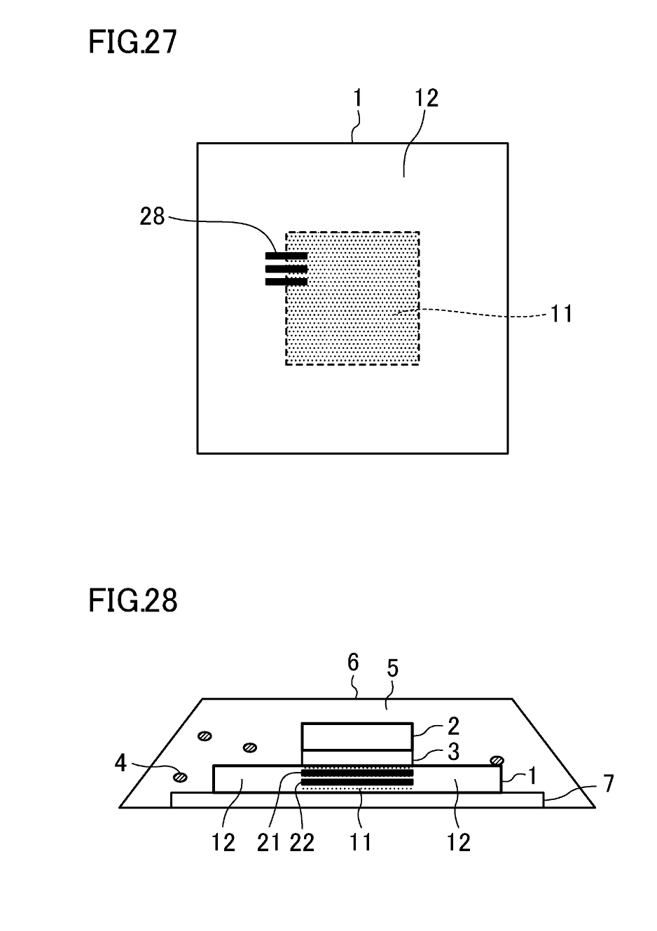

FIG. 26 is a cross-sectional view illustrating a configuration of a multi-chip semiconductor device of a third embodiment, and FIG. 27 is a plan view illustrating a state of an interconnect layer of a first semiconductor chip 1 of the present embodiment.

In FIGS. 26 and 27, a semiconductor device 6 includes the first semiconductor chip 1 fixed to a die pad 7, a second semiconductor chip 2 stacked on the first semiconductor chip 1 with an adhesive layer 3 being interposed therebetween, and molding resin 5 provided as an example of resin for sealing the first and second semiconductor chips 1, 2. The second semiconductor chip 2 is fixed onto the first semiconductor chip 1 by the adhesive layer 3. The molding resin 5 is, e.g., epoxy resin, and contains a mixture having a filler 4 as a main component.

The first semiconductor chip 1 is divided into a first region 11 on a surface of which the second semiconductor chip 2 is stacked, and a second region 12 on a surface of which the second semiconductor chip 2 is not stacked. In the present embodiment, as illustrated in FIG. 27, a plurality of wiring patterns 28 which are at the same potential extend across a border between the first and second regions 11, 12 in at least one of interconnect layers including an uppermost layer. That is, the plurality of wiring patterns 28 which are at the same potential are provided so as to extend across the border between the first and second regions 11, 12.

According to such a configuration, even if the filler 4 contained in the molding resin 5 enters end portions of the adhesive layer 3 by a sealing pressure of the molding resin 5, and a surface of the first semiconductor chip 1 is damaged, it is less likely to damage all of the plurality of wiring patterns 28, and the damage provides an impact only on the first region 11. As in the foregoing, a predetermined condition for arranging the interconnects in the first region 11 is provided, and therefore the semiconductor device 6 can be normally operated even if the damage of the surface of the first semiconductor chip 1 is caused due to the filler 4. Thus, improper assembly can be reduced, thereby realizing a cost reduction.

It is preferred that a width of the wiring pattern 28 is larger than a particle size of the filler 4. In such a case, even if the filler 4 contained in the molding resin 5 enters the end portions of the adhesive layer 3 by the sealing pressure of the molding resin 5, and the surface of the first semiconductor chip 1 is damaged, disconnection is not caused because of the wiring pattern width larger than the particle size of the filler 4. Thus, the first semiconductor chip 1 and the semiconductor device 6 can be normally operated.

Note that a single wiring pattern 28 may extend across the border between the first and second regions 11, 12. In such a case, it is preferred that the width of the wiring pattern 28 is larger than the particle size of the filler 4.

Further, as illustrated in FIG. 28, the first semiconductor chip 1 may include, in addition to the foregoing wiring pattern, a first power supply interconnect 21 formed across substantially an entire surface of the first region 11 in the uppermost layer, and a second power supply interconnect 22 formed in a lower layer of the uppermost layer. In such a case, even if the surface of the first semiconductor chip 1 is damaged due to the filler 4, the damage provides an impact only on a limited region of the first power supply interconnect 21 covering the entire surface of the first region 11. Thus, the disconnection is not caused. In addition, the first power supply interconnect 21 covers the entire surface of the first region 11, thereby enhancing a power supply. Thus, the first semiconductor chip 1 and the semiconductor device 6 can be normally operated.

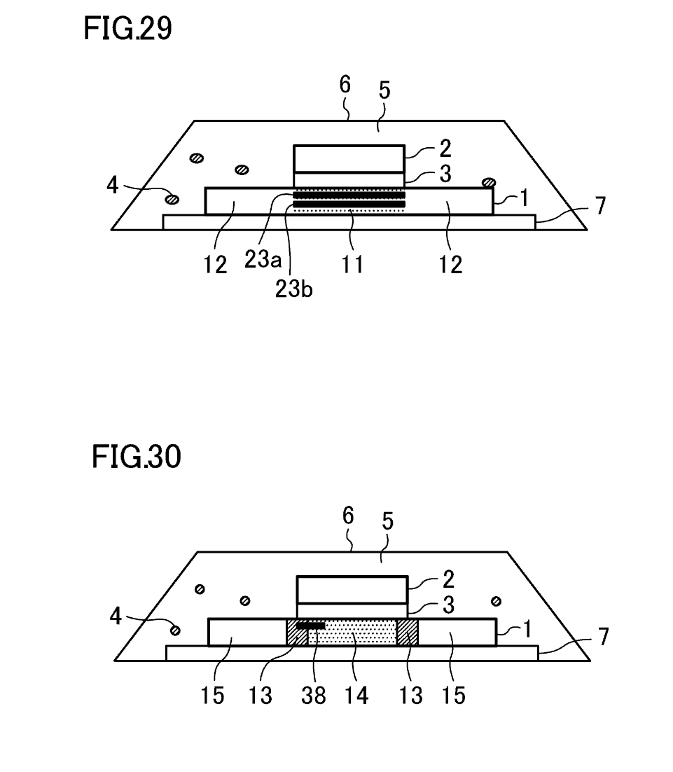

Further, as illustrated in FIG. 29, the first semiconductor chip 1 may include, in addition to the foregoing wiring pattern, a first electrode pattern 23a formed across substantially the entire surface of the first region 11 in the uppermost layer, and a second electrode pattern 23b formed in the lower layer of the uppermost layer and forming a capacitative element together with the first electrode pattern 23a. In such a case, even if the surface of the first semiconductor chip 1 is damaged due to the filler 4, the damage provides an impact only on a limited region of the first electrode pattern 23a covering the entire surface of the first region 11. Thus, the disconnection is not caused. In addition, since the capacitative element is formed across the entire surface of the first region 11, there is an advantage that a power supply can be stabilized when, for example, the capacitive element is used as a smoothing capacitor by applying power supply voltage to the first electrode pattern 23a and applying ground voltage to the second electrode pattern 23b. Thus, the first semiconductor chip 1 and the semiconductor device 6 can be normally operated. Note that, if the capacitive element is used as the smoothing capacitor, voltage other than the power supply voltage and the ground voltage may be applied to the first electrode pattern 23a and the second electrode pattern 23b.

Note that the adhesive layer 3 may be in any forms, i.e., may be a substrate such as an interposer, a sheet, a liquid, etc.

### Fourth Embodiment

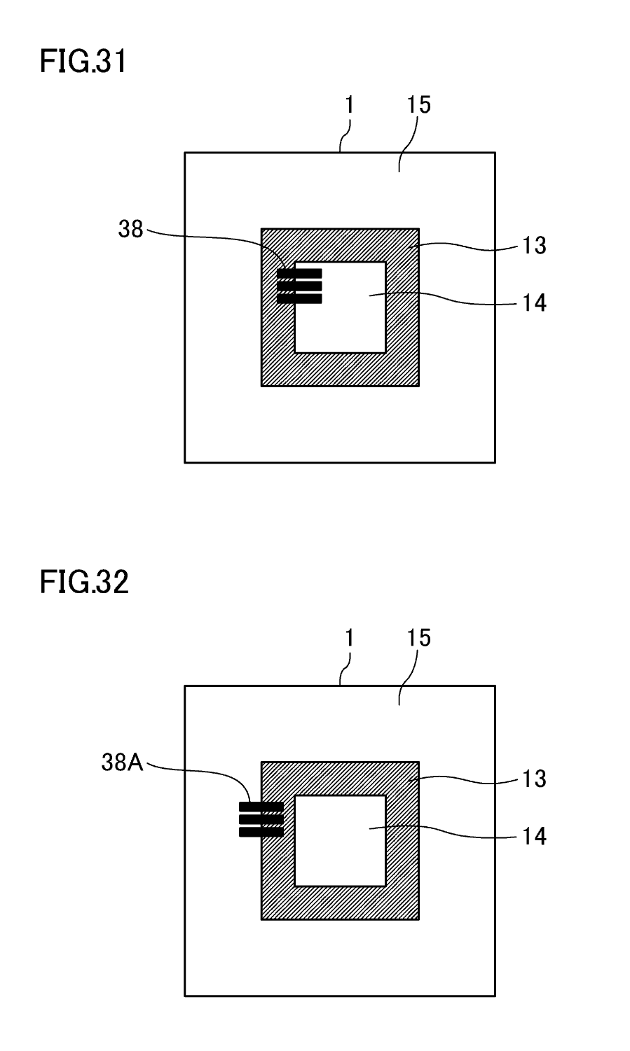

FIG. 30 is a cross-sectional view illustrating a configuration of a multi-chip semiconductor device of a fourth embodiment, and FIGS. 31 and 32 are plan views illustrating states of an interconnect layer of a first semiconductor chip 1 of the present embodiment.

In FIGS. 30-32, a semiconductor device 6 includes the first semiconductor chip 1 fixed to a die pad 7, a second semiconductor chip 2 stacked on the first semiconductor chip 1 with an adhesive layer 3 being interposed therebetween, and molding resin 5 provided as an example of resin for sealing the first and second semiconductor chips 1, 2. The second semiconductor chip 2 is fixed onto the first semiconductor chip 1 by the adhesive layer 3. The molding resin 5 is, e.g., epoxy resin, and contains a mixture having a filler 4 as a main component.

The first semiconductor chip 1 is divided into a third region 13 which is a circular or rectangular region on a surface of which a circumferential end portion of the second semiconductor chip 2 is positioned, a fourth region 14 which is a region inside the third region 13, and a fifth region 15 which is a region outside the third region 13. The third region 13 includes an outer circumferential portion of the first region 11 described in the first embodiment, and extends over the second region 12. The fourth region 14 and the fifth region 15 correspond part of the first region 11 other than the third region 13 and part of the second region 12 other than the third region 13, respectively. Note that the third region 13 is a circular region in FIGS. 31 and 32, but may be the rectangular region as in FIG. 12 illustrating the second embodiment.

In the present embodiment, as illustrated in FIG. 31, a plurality of wiring patterns 38 which are at the same potential extend across a border between the third and fourth regions 13, 14 in at least one of interconnect layers including an uppermost layer. According to such a configuration, even if the filler 4 contained in the molding resin 5 enters end portions of the adhesive layer 3 by a sealing pressure of the molding resin 5, and a surface of the first semiconductor chip 1 is damaged, it is less likely to damage all of the plurality of wiring patterns 38, and the damage provides an impact only on the third region 13. As in the foregoing, a predetermined condition for arranging the interconnects in the third region 13 is provided, and therefore the semiconductor device 6 can be normally operated even if the damage of the surface of the first semiconductor chip 1 is caused due to the filler 4. Thus, improper assembly can be reduced, thereby realizing a cost reduction. According to the present embodiment, since the interconnects are formed across the circular or rectangular region on the surface of which the circumferential end portion of the second semiconductor chip is positioned, considering the impact of the filler, the similar advantages can be realized if a position of the second semiconductor chip is displaced.

As illustrated in FIG. 32, a plurality of wiring patterns 38A which are at the same potential may be provided so as to extend across a border between the third and fifth regions 13, 15 in the at least one of interconnect layers including the uppermost layer. According to such a configuration, advantages similar to those of the configuration illustrated in FIG. 31 can be realized.

Note that it is preferred that a width of the wiring pattern 38 is larger than a particle size of the filler 4. In such a case, even if the filler 4 contained in the molding resin 5 enters the end portions of the adhesive layer 3 by the sealing pressure of the molding resin 5, and the surface of the first semiconductor chip 1 is damaged, disconnection is not caused because of the wiring pattern width larger than the particle size of the filler 4. Thus, the first semiconductor chip 1 and the semiconductor device 6 can be normally operated.

Note that a single wiring pattern 38 may extend across the border between the third and fourth regions 13, 14, and a single wiring pattern 38A may extend across the border between the third and fifth regions 13, 15. In such a case, it is preferred that the width of the wiring pattern 38, 38A is larger than the particle size of the filler 4.

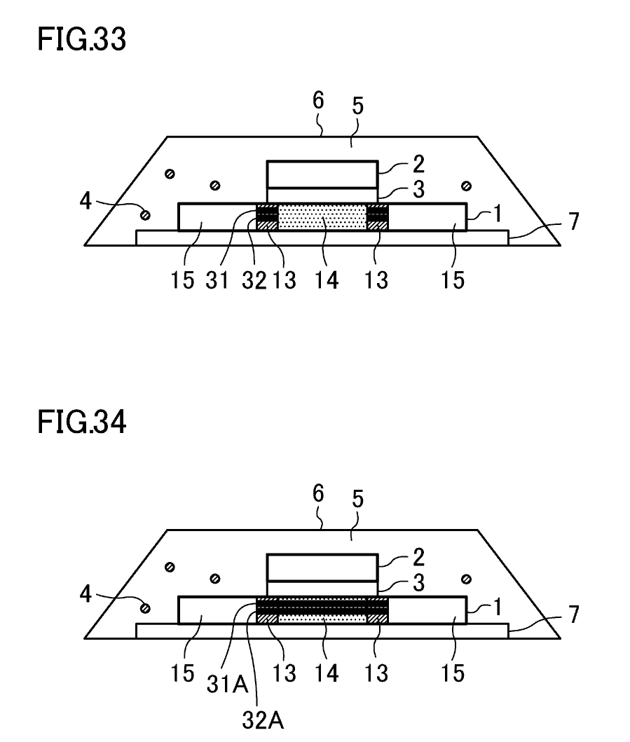

Further, as illustrated in FIG. 33, the first semiconductor chip 1 may include, in addition to the foregoing wiring pattern, a first power supply interconnect 31 formed across substantially an entire surface of the third region 13 in the uppermost layer, and a second power supply interconnect 32 formed in a lower layer of the uppermost layer. Alternatively, as illustrated in FIG. 34, the first semiconductor chip 1 may include, in addition to the foregoing wiring pattern, a first power supply interconnect 31A formed across substantially an entire surface of the third and fourth regions 13, 14 in the uppermost layer, and a second power supply interconnect 32A formed in the lower layer of the uppermost layer. In such a case, even if the surface of the first semiconductor chip 1 is damaged due to the filler 4, the damage provides an impact only on a limited region of the first power supply interconnect 31, 31A covering the entire surface of the third region 13 or the entire surface of the third and fourth regions 13, 14. Thus, the disconnection is not caused. In addition, the first power supply interconnect 31 covers the entire surface of the third region 13 or the entire surface of the third and fourth regions 13, 14, thereby enhancing a power supply. Thus, the first semiconductor chip 1 and the semiconductor device 6 can be normally operated.

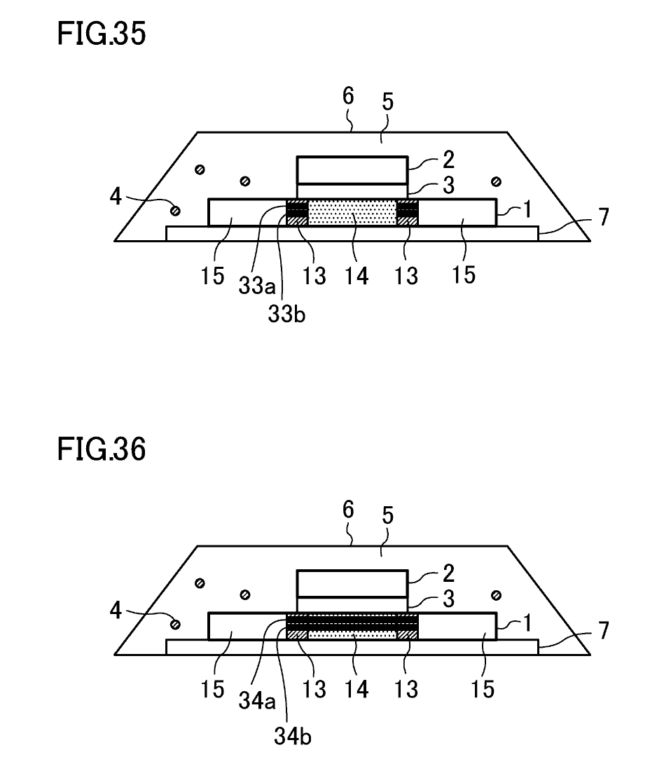

Further, as illustrated in FIG. 35, the first semiconductor chip 1 may include, in addition to the foregoing wiring pattern, a first electrode pattern 33a formed across substantially the entire surface of the third region 13 in the uppermost layer, and a second electrode pattern 33b formed in the lower layer of the uppermost layer and forming a capacitative element together with the first electrode pattern 33a. Alternatively, as illustrated in FIG. 36, the first semiconductor chip 1 may include, in addition to the foregoing wiring pattern, a first electrode pattern 34a formed across substantially the entire surface of the third and fourth regions 13, 14 in the uppermost layer, and a second electrode pattern 34b formed in the lower layer of the uppermost layer and forming a capacitative element together with the first electrode pattern 34a. In such a case, even if the surface of the first semiconductor chip 1 is damaged due to the filler 4, the damage provides an impact only on a limited region of the first electrode pattern 33a, 34a covering the entire surface of the third region 13 or the entire surface of the third and fourth regions 13, 14. Thus, the disconnection is not caused. In addition, since the capacitative element is formed across the entire surface of the third region 13 or the entire surface of the third and fourth regions 13, 14, there is an advantage that a power supply can be stabilized when, for example, the capacitive element is used as a smoothing capacitor by applying power supply voltage to the first electrode pattern 33a, 34a and applying ground voltage to the second electrode pattern 33b, 34b. Thus, the first semiconductor chip 1 and the semiconductor device 6 can be normally operated. Note that, if the capacitive element is used as the smoothing capacitor, voltage other than the power supply voltage and the ground voltage may be applied to the first electrode pattern 33a, 34a and the second electrode pattern 33b, 34b.

Note that the adhesive layer 3 may be in any forms, i.e., may be a substrate such as an interposer, a sheet, a liquid, etc.

### Fifth Embodiment

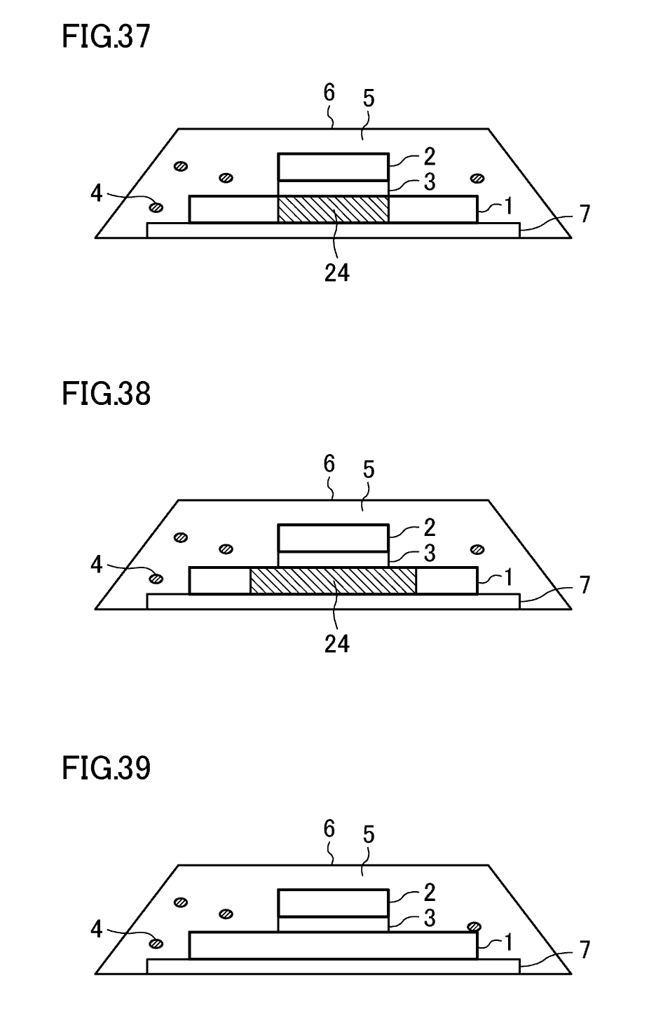

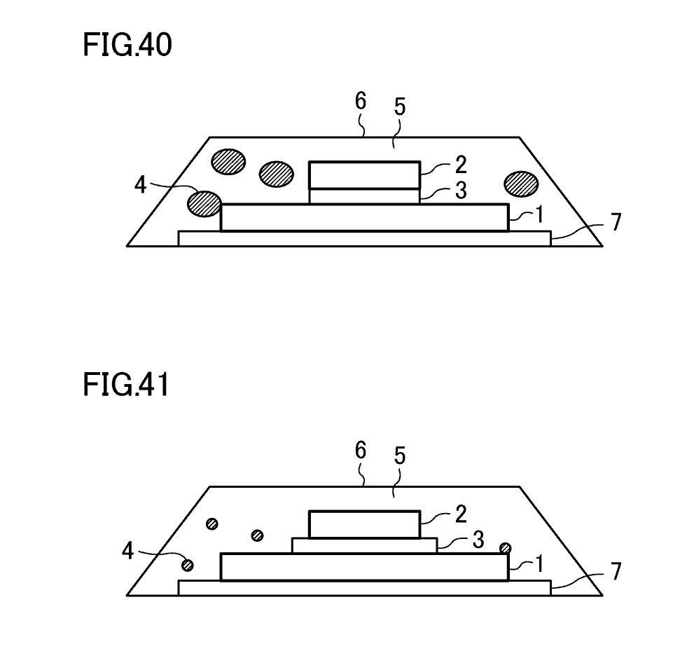

FIG. 37 is a cross-sectional view illustrating a multi-chip semiconductor device of a fifth embodiment. In FIG. 37, a semiconductor device 6 includes a first semiconductor chip 1 having a memory cell array 24, a second semiconductor chip 2 stacked on the first semiconductor chip 1 with an adhesive layer 3 being interposed therebetween, and molding resin 5 provided as an example of resin for sealing the first and second semiconductor chips 1, 2. The molding resin 5 is, e.g., epoxy resin, and contains a mixture having a filler 4 as a main component.

In the first semiconductor chip 1 of the present embodiment, the memory cell array 24 is arranged in an area corresponding to a region on a surface of which the second semiconductor chip 2 is stacked. According to such a configuration, even if the filler 4 contained in the molding resin 5 enters end portions of the adhesive layer 3 by a sealing pressure of the molding resin 5, and a surface of the first semiconductor chip 1 is damaged, the damage provides an impact only on the memory cell array 24. Thus, even if the damage of the surface of the first semiconductor chip 1 is caused due to the filler 4, the semiconductor device 6 can be normally operated by, e.g., setting an access to a damaged memory cell in an inhibited state or redundantly replacing a damaged memory cell. Consequently, improper assembly can be reduced, thereby realizing a cost reduction. For the foregoing reason, it is preferred that the semiconductor device 6 is configured so that, when part of memory cells of the memory cell array 24 becomes defective, an access to the defective memory cell can be set to an inhibited state or the defective memory cell can be redundantly replaced.

Note that, as illustrated in FIG. 38, the memory cell array 24 may be larger than the region on the surface of which the second semiconductor chip 2 is stacked in the first semiconductor chip 1. That is, as long as the memory cell array 24 is arranged in an area including the region on the surface of which the second semiconductor chip 2 is stacked, advantages similar to the foregoing can be realized.

Note that the adhesive layer 3 may be in any forms, i.e., may be a substrate such as an interposer, a sheet, a liquid, etc.

Note that a method for electrically connecting the first and second semiconductor chips 1, 2 together in each of the foregoing embodiments is not limited, and any methods such as connection through a bonding wire or a via may be employed.

In the foregoing embodiments, the example has been described, in which the two semiconductor chips are stacked. However, the present disclosure is not limited to the configuration in which the two semiconductor chips are stacked, and is similarly applicable to a semiconductor device in which three or more semiconductor chips are stacked.

The semiconductor device of the present disclosure can be normally operated even if the chip damage is caused due to the mixture of the filler etc., which is contained in the sealing resin. Thus, the semiconductor device of the present disclosure is useful under conditions limiting, e.g., selection of the filler and the adhesive layer.

What is claimed is:

1. A semiconductor device, comprising:
a first semiconductor chip;
a second semiconductor chip stacked on the first semiconductor chip with an adhesive layer being interposed therebetween; and
resin for sealing the first and second semiconductor chips,
wherein the first semiconductor chip includes
a first region on a surface of which the second semiconductor chip is stacked, and
a second region on a surface of which the second semiconductor chip is not stacked, and
in at least one of interconnect layers including an uppermost layer of the first semiconductor chip, a wiring pattern for an interconnect to be used for an operation of the first semiconductor chip is provided so as not to extend across a border between the first and second regions.

2. The semiconductor device of claim 1, wherein
in the at least one of interconnect layers including the uppermost layer of the first semiconductor chip, the interconnect to be used for the operation of the first semiconductor chip is not arranged in the first region.

3. The semiconductor device of claim 1, wherein
in the at least one of interconnect layers including the uppermost layer of the first semiconductor chip, a dummy pattern is provided, which extends across the border between the first and second regions.

4. The semiconductor device of claim 1, wherein
in the at least one of interconnect layers including the uppermost layer of the first semiconductor chip, at least any one of a disused interconnect, a disused element, and a dummy pattern which are not to be used for the operation of the first semiconductor chip is arranged in the first region.

5. The semiconductor device of claim 4, wherein
in the at least one of interconnect layers including the uppermost layer of the first semiconductor chip, an element for evaluating transistor characteristics is arranged as the disused element in the first region.

6. The semiconductor device of claim 4, wherein
in the at least one of interconnect layers including the uppermost layer of the first semiconductor chip, a honeycomb-shaped wiring pattern is provided as the disused interconnect in the first region.

7. The semiconductor device of claim 4, wherein
in the at least one of interconnect layers including the uppermost layer of the first semiconductor chip, a wiring pattern which is a grid pattern, a rectangular pattern, or a striped pattern is provided as the disused interconnect in the first region.

8. The semiconductor device of claim 4, wherein
in the at least one of interconnect layers including the uppermost layer of the first semiconductor chip, a wiring pattern is formed so as to cover an entire surface of the first region.

9. The semiconductor device of claim 1, wherein
in an interconnect layer other than the uppermost layer of the first semiconductor chip, a signal line and a power supply line are arranged so as to extend across the border between the first and second regions.

10. A semiconductor device, comprising:
a first semiconductor chip;
a second semiconductor chip stacked on the first semiconductor chip with an adhesive layer being interposed therebetween; and
resin for sealing the first and second semiconductor chips,
wherein the first semiconductor chip includes
a third region which is a circular or rectangular region on a surface of which a circumferential end portion of the second semiconductor chip is positioned,
a fourth region which is a region inside the third region, and
a fifth region which is a region outside the third region, and
in at least one of interconnect layers including an uppermost layer of the first semiconductor chip, a wiring pattern for an interconnect to be used for an operation of the first semiconductor chip is provided so as not to extend across a border between the third and fourth regions and a border between the third and fifth regions.

11. The semiconductor device of claim 10, wherein
in the at least one of interconnect layers including the uppermost layer of the first semiconductor chip, the interconnect to be used for the operation of the first semiconductor chip is not arranged in the third region or the third and fourth regions.

12. The semiconductor device of claim 10, wherein
in the at least one of interconnect layers including the uppermost layer of the first semiconductor chip, a dummy pattern extending across the border between the third and fourth regions, or a dummy pattern extending across the border between the third and fifth regions is provided.

13. The semiconductor device of claim 10, wherein
the resin is molding resin containing a mixture, and
a width of the third region is larger than a particle size of the mixture.

14. The semiconductor device of claim 10, wherein
in the at least one of interconnect layers including the uppermost layer of the first semiconductor chip, at least any one of a disused interconnect, a disused element, and a dummy pattern which are not to be used for the operation of the first semiconductor chip is arranged in the third region or the third and fourth regions.

15. The semiconductor device of claim 14, wherein
in the at least one of interconnect layers including the uppermost layer of the first semiconductor chip, an element for evaluating transistor characteristics is arranged as the disused element in the third region or the third and fourth regions.

16. The semiconductor device of claim 14, wherein
in the at least one of interconnect layers including the uppermost layer of the first semiconductor chip, a honeycomb-shaped wiring pattern is provided as the disused interconnect in the third region or the third and fourth regions.

17. The semiconductor device of claim 14, wherein
in the at least one of interconnect layers including the uppermost layer of the first semiconductor chip, a wiring pattern which is a grid pattern, a rectangular pattern, or a striped pattern is provided as the disused interconnect in the third region or the third and fourth regions.

18. The semiconductor device of claim 14, wherein
in the at least one of interconnect layers including the uppermost layer of the first semiconductor chip, a wiring pattern is formed so as to cover an entire surface of the third region or the third and fourth regions.

19. The semiconductor device of claim 10, wherein
in an interconnect layer other than the uppermost layer of the first semiconductor chip, a signal line and a power supply line which extend across the border between the third and fourth regions, and a signal line and a power supply line which extend across the border between the third and fifth regions are arranged.
